(19) United States
(12) Patent Application Publication
(10) Pub. No.: US 2013/0215582 A1
(43) Pub. Date: Aug. 22, 2013

(54) CONTROL DEVICE ASSEMBLY

(71) Applicants: Jörg Dittrich, Ammerthal (DE); Herbert Wallner, Auerbach (DE); Hermann Josef Robin, Regensburg (DE); Josef Loibl, Bad Abbach (DE)

(72) Inventors: Jörg Dittrich, Ammerthal (DE); Herbert Wallner, Auerbach (DE); Hermann Josef Robin, Regensburg (DE); Josef Loibl, Bad Abbach (DE)

(21) Appl. No.: 13/806,620

(22) PCT Filed: Jun. 1, 2011
(86) PCT No.: PCT/EP2011/059099

§ 371 Date: May 8, 2013

(30) Foreign Application Priority Data
Jul. 2, 2010 (DE) 102010030891.9

(51) Int. Cl. H05K 5/06

(52) U.S. Cl. CPC H05K 5/061
USPC 361/752

(57) ABSTRACT

The invention relates to a control device assembly, in particular for a motor vehicle, comprising a printed circuit board that receives the control device electronics. At least one discretely formed frame element is supported on a populated face of the printed circuit board, enclosing at least one electronic component. A seal sits against an outer circumferential surface of the frame element, said seal surrounding the circumferential surface, and the seal is pressed against the printed circuit board by a housing element in order to form an electronic chamber that is sealed in a media-tight manner.

The present invention relates to a control device assembly in accordance with the generic term of claim 1.

State of the art control devices, in particular those for use in motor vehicles, such as transmission or engine control devices, usually have a housing to protect the control device electronics against environmental influences. The housing embraces the electronic components or encapsulates these, utilizing one or more media-tight seals.

Control devices, which are formed by means of a rigid printed circuit board, which, e.g., protrudes from the housing for contacting purposes, are generally formed as a housing consisting of an upper and e.g. a lower housing component. In a well-known variant a high pressure die casting is used as upper housing component and lower housing component, between which the printed circuit board is arranged. A circumferential groove is formed in the respective high pressure die castings, into which a seal is inserted, in order to abut against the printed circuit board for sealing purposes. The production of such high pressure die castings is expensive, however.

In case of a further known variant, e.g., an aluminum sheet is used as the upper housing component, which is transformed in complex fashion to form a receiving groove for a seal, as well as the necessary cavity for capping the components that require encapsulating. The lower housing component, as before, consists of an aluminum high pressure die casting. Although the upper housing component is cheaper to manufacture than an aluminum high pressure die casting, its complex form still makes it costly.

A control device electronics housing is known from the publication DE 39 33 084 A1, in which a cooling frame is provided, and on which upper and lower housing components, as well as a printed circuit board populated on one side are arranged. As a disadvantage, this requires complex transforming processes for forming a groove that accommodates the seal and for forming the cooling frame.

On this basis, it is the task of the present invention to overcome the above described disadvantages of the state of the art and to propose a control device assembly, which provides a simple and cost-effective housing and sealing for the control device electronics.

This task is achieved by the inventive features of claim 1.

According to the invention, a control device assembly is proposed, in particular for a motor vehicle featuring a printed circuit board that receives the control device electronics, with at least one discretely formed frame element supported on a populated face of the printed circuit board, enclosing at least one electronic component. A seal abuts against an outer circumferential surface of the frame element, said seal surrounding the circumferential surface, and the seal is pressed against the printed circuit board by a housing element in order to form an electronic chamber that is sealed in a media-tight manner.

One inventive embodiment of the control device assembly features the frame element formed separately from the housing element, which is comprised of an upper and lower housing component, and the printed circuit board.

In a further inventive embodiment of the control device assembly the frame element is permanently arranged at the printed circuit board, especially plugged into the printed circuit board.

In yet a further inventive embodiment of the control device assembly the frame element is made of plastic or sheet metal.

In accordance with an aspect of the inventive control device assembly, the frame element is permanently attached to the housing element, in particular installed in it.

In accordance with a further aspect of the inventive control device assembly, the housing element is formed as a plate, in particular as a flat plate.

In accordance with yet a further aspect of the inventive control device assembly, the printed circuit board is connected to the frame element in thermally conductive fashion and the frame element to the housing element in thermally conductive fashion.

According to the invention, a control device assembly is also proposed, said control device assembly featuring a frame element with a rectangular profile between the printed circuit board and the housing element.

According to the invention, a further control device assembly is proposed, said control device assembly featuring a frame element surrounded by a seal and enclosing at least one electronic component, arranged at a first and a second opposing face of the printed circuit board, respectively, said seal being pressed against the printed circuit board, thereby forming a first and second electronic chamber, both sealed in a media-tight manner.

In an inventive embodiment of the control device assembly, at least one strap is arranged at a housing element of the control device assembly, for purposes of connecting with a further housing element.

Further features and advantages of the invention arise from the following description of embodiments of the invention, on the basis of the figures of the drawings, which show important inventive details, and from the claims. The individual features can be implemented individually or in groups of several in any combination for a variant of the invention.

Preferred embodiments of the invention will be explained in more detail below, based on the attached drawings. The figures depict the following:

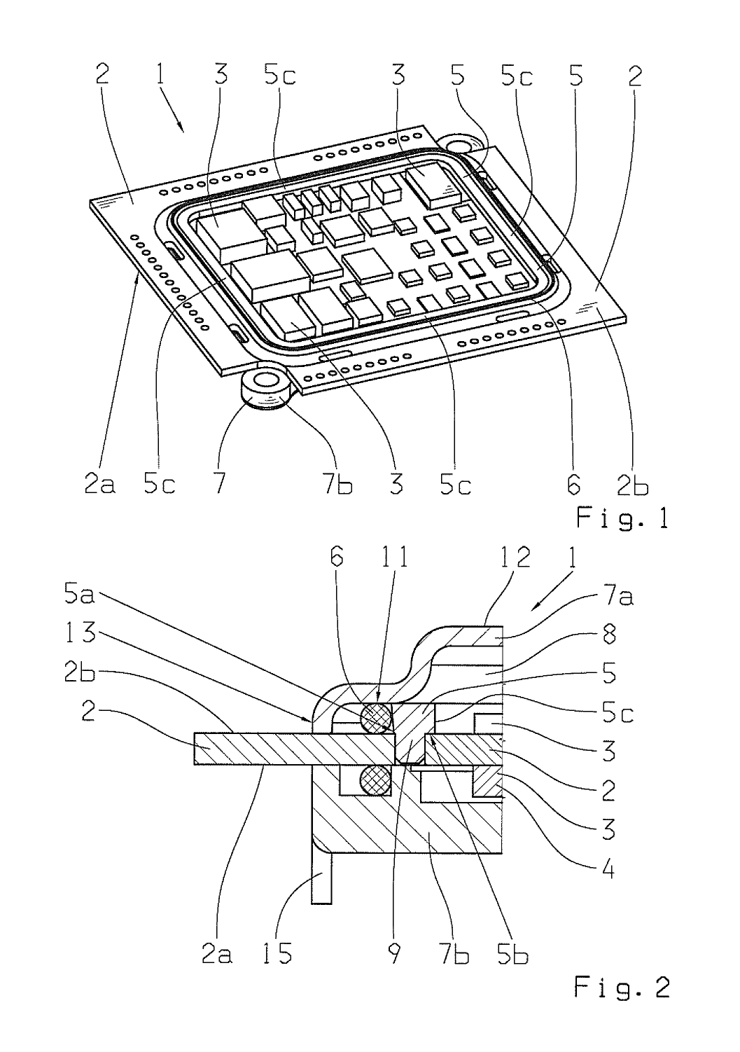

FIG. 1 Example of a control device assembly without upper housing component in accordance with a possible embodiment of the invention;

FIG. 2 Example of a truncated cross-sectional view of a control device assembly, in accordance with a possible embodiment of the invention;

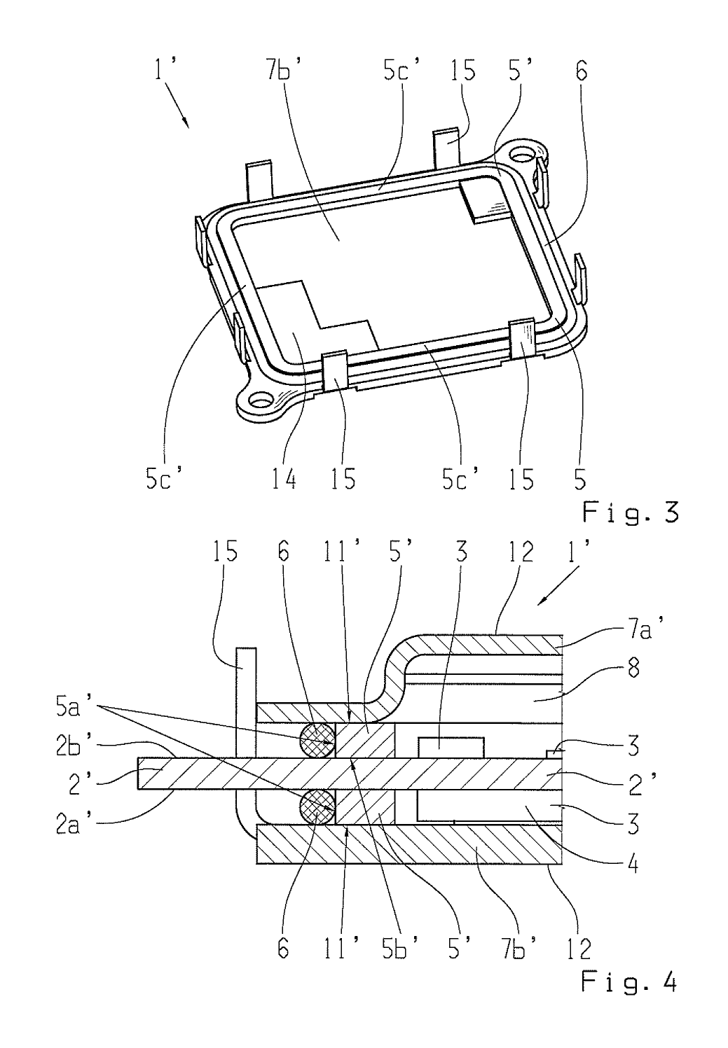

FIG. 3 Example of a housing element of a control device assembly, in accordance with a further possible embodiment of the invention; and

FIG. 4 Example of a truncated cross-sectional view of a control device assembly, in accordance with the further possible embodiment of the invention.

In the subsequent figure descriptions, same elements or functions have the same reference numbers.

FIG. 1 shows an example of an inventive control device assembly 1 with a housing element removed. The control device assembly 1 features a printed circuit board 2, on which electronic components or components 3 of a control device circuit, in particular the control device electronics are accommodated or formed. The electronic components 3 comprise, for example, a micro controller and/or processor, transistors and, e.g., further power components, etc. The control device formed by the control device electronics is, e.g., a transmission control device or an engine control device, i.e., a control device for a motor vehicle.

According to the invention, the printed circuit board 2 is formed as a rigid printed circuit board, e.g., an epoxy or FR4 printed circuit board, in particular a multi-layered or multilayer printed circuit board. Preferably, the printed circuit board 2 is, e.g., an HDI printed circuit board, in which a beneficially high degree of integration of the electronic components 3 can be achieved. For networking of the electronic components 3, conducting paths and, e.g., through-connections or vias are formed on the printed circuit board 2. The printed circuit board 2 is populated on one face or preferably on both faces. For example, a micro controller 4 is arranged at the first face 2a of the printed circuit board 2, e.g., a bottom face, and further components 3, e.g., are arranged at the opposing second face 2b, e.g., a top face.

According to the invention, an independently formed frame or frame element 5 is arranged at or supported on the printed circuit board 2, e.g., at the populated first face 2b, i.e., manufactured in a separate process. The frame element 5, e.g., is formed from plastic or, e.g., sheet metal and intended for forming a support for guiding a housing sealing 6, which interacts, inter alia, with a housing element 7a, in particular a capping housing element 7a. Such a design allows for the formation of a protected electronic chamber 8 for the electronic components 3, i.e., a media-tight electronic chamber 8.

The inventive frame element 5 encloses at least one electronic component 3 incorporated at the populated face 2b of the printed circuit board, preferably several or all such components 3, i.e., as a group, or surrounds them or frames them. The frame element 5 is preferably formed as a continuous frame, but can be segmented, if necessary. The components 3 that require particular protection from damaging influences are enclosed as a group by the frame stays 5c, which form a frame 5, FIG. 1, which, e.g., are formed integrally.

In order to appropriately support a seal 6, which is intended for leaning against the outer circumferential surface 5a of the frame element 5, enclosing said frame element, and to guide said seal around the components 3 that are enclosed by the housing element 7a, the frame element 5 is supported on the printed circuit board 2, e.g., as shown in FIGS. 1 and 2, plugged into said printed circuit board with accurate positioning. The frame element 5 features corresponding mounting edges 9, which protrude from a frame element contact surface 5b, intend for support at the printed circuit board 2, and mesh with the corresponding recesses 10 of the printed circuit board 2, e.g., by press fit. Other mounting options for the frame element 5 on the printed circuit board 2 are also conceivable, e.g., bonding, fitting, welding, or more.

The frame element 5, e.g., has a rectangular form, i.e., a frame form, e.g., said frame form has rounded edges, as shown in FIG. 1. In a profile or cross-sectional view of a frame stay 5C the frame element 5 also has a rectangular shape, e.g., FIG. 2, with the exception of the plug connection edges, which face downward or extend into the printed circuit board 2. There are other forms that can be used as frame form, however.

The frame element 5 is permanently arranged within the outline of the printed circuit board, so that said printed circuit board extends beyond the frame element 5 and enables an electric contact in a simple manner, e.g., by press fit pins, stamping grids, etc.

As mentioned before, to seal or create a media-tight electronic chamber 8, a seal 6, e.g., a ring-shaped seal or form seal, in particular an elastic seal, abuts against the outer or outer circumferential surface 5a of the independently formed frame element 5. The outer circumferential frame element 5a is supported on the printed circuit board 2. The seal 6 is arranged to surround or enclose the frame element 5. The frame element 5 that reaches through the seal 6 supports or accurately fixes the position of said seal 6. The seal 6 abuts against the circuit board 2, i.e, against the second face 2b of the printed circuit board 2, on which the frame element 5 rests, FIG. 2.

For the purpose of creating a protected electronic chamber 8 or a housing for at least one electronic component 3, which is arranged at the populated face of the printed circuit board 2b, a capping or cap-forming housing element 7a, e.g., an upper housing component, is arranged at the printed circuit board 2 pressing against seal 6, which projects beyond without overlying the housing component 7a and compresses the frame element 5 in the direction of the printed circuit board 2 over its entire length, thereby compressing said seal 6 over its entire length, thereby providing a reliable seal, between the printed circuit board 2 and the capping housing component 7a. The housing element 7a that abuts against the seal 6 presses said seal 6 against the printed circuit board 2 and the outer circumferential surface 5a, e.g., in addition to a corresponding preload against the outer circumferential surface 5a.

The housing element 7a, which, according to the invention, is a housing element made from transformed sheet metal, e.g., aluminum sheet metal, is fixed at the printed circuit board 2, e.g., with a further capping housing element 7b, e.g., a lower housing component, fitted, locked in place, snapped in place, braced, flanged, etc. Due to the inventive design, a more complex form of the housing element 7a for receiving and fixing the seal 6 is not necessary, as opposed to the state of the art. Thus, a cost-effective housing element 7a can be used, which does not require complex transformation.

The inventive housing element 7a forms an advantageous flat contact area 11 that abuts against seal 6, said contact area allowing for the meshing and thereby the capturing of the seal. The contact area 11 corresponds with the form of the seal 6, which surrounds the frame 5 and resting on the printed circuit board 2, and surrounds the housing element 7a, e.g., as a flange section, which extends parallel to the surface of the printed circuit board 2b. Within the surrounding flat contact area 11, e.g., the capping area 12 of the housing element 7a is formed, wherein said area caps the components 3. Outside the contact area 11, e.g., an offset area 13 is formed, which is supported on the printed circuit board 2, thereby protecting the seal 6 from harmful influences.

FIG. 2 shows a further populated face 2a, e.g., which can be capped in a conventional manner with an aluminum high pressure die casting. Alternatively, according to the invention, the further populated face 2a can be capped by an independently formed frame element 5 and sealed, i.e., as described above for the printed circuit board face 2a. For example, a frame element 5 is intended for each populated face of a printed circuit board 2a or 2b, and interacts, as described above, with a seal 6 and a corresponding housing element 7a or 7b for the formation of a media-tight electronic chamber. The further housing element 7b is, e.g., also made of aluminum sheet metal.

In order to form an inventive control device assembly 1 in accordance with the above described embodiments, first the separately manufactured frame element 5 is provided and, in a further step, is plugged into the printed circuit board 2 or permanently arranged on it. In a subsequent step, the seal 6 is arranged around the frame element 5 and abuts against its outer circumferential surface 5a. In a further step, the housing element 7a abuts against the frame element 5 and the seal 6 and is permanently fixed to the printed circuit board 2, wherein the seal 6 is pressed against the printed circuit board 2 on the one hand and against the housing element 7a on the other hand. This seals the electronic chamber 8 between printed circuit board 2 and housing element 7a.

FIGS. 3 and 4 show a further inventive embodiment of a control device assembly 1′, wherein FIG. 3 shows a housing element 7b′ with an independently formed frame element 5′ arranged on said housing element. Unlike in the above described embodiment, the further embodiment features an independently manufactured or formed frame element 5′, which is not inserted into or permanently arranged at the printed circuit board 2, but inserted into or permanently arranged at a housing element 7a′ or 7b′. The frame element 5′ is manufactured from the same material, e.g., as the respective housing element 7a′, 7b′, e.g., from aluminum or aluminum sheet metal and can, e.g., easily formed from sheet metal by simple punching. Alternatively, the frame element 5′ can be formed from material that is different from the material used for the housing element 7a′ or 7b′.

The frame element 5′, e.g., features a rectangular form, wherein the frame stays 5c′, e.g., also features a rectangular profile. The contact surface 5b′ in particular does not feature any mounting elements, but is entirely flat.

The invention intends, for stability reasons, that the frame element 5′ is permanently connected to the housing element 7a′ or 7b′, e.g., a lower housing component 7b′ or an upper housing component 7a′, e.g., by bonding or welding, etc. However, housing element 7a′ or 7b′ and the respective frame element 5′ do not necessarily need to be connected permanently, in order to create the desired functionality of creating a sealed electronic chamber 8.

In a further embodiment the frame element 5′ is respectively arranged at the corresponding side of the housing element 7a′ or 7b′, which is intended to form an inner surface of a cap for the electronic components 3. For this purpose the housing element 7a′ or 7b′, e.g., respectively forms a circumferential flat contact area 11′, at which the frame element 5′ with its corresponding form is arranged and which also is intended for abutting against a seal 6 that surrounds said frame element. The dimensions of the respective frame element 5′ allow for the surrounding of the components 3 that need protection and for a support on the printed circuit board 2′. The printed circuit board 2′ forms, e.g., no mounting elements for the frame element 5′ and the housing element 7a′ or 7b′ forms no offset area 13.

A seal 6 of the above described design surrounds the respective frame element 5′, such that the seal 6 abuts against the outer circumferential surface 5a′ of the frame element 5′. The housing element 7a′ or 7b′, in turn, is respectively fixed to the printed circuit board 2′, e.g., fitted or braced to the further housing element 7b′ or 7a′ on the opposing side 2a′ or 2b′ of the printed circuit board, etc. The further inventive embodiment also permits the use of a more cost-effective housing element 7a′ or 7b′, which requires no complex transformation.

As part of the arrangement of frame element 5′ and housing element 7′ on the printed circuit board 2′, the seal is clamped between printed circuit board 2′ and housing element 7′, which leads to the sealing of an electronic chamber 8. In the course of this, the frame element 5′ is supported on the printed circuit board 2′.

The invention intends, in particular in case of a printed circuit board 2′ that is populated on both faces, to respectively furnish both a housing element 7a′, e.g., in form of an upper housing component, and a housing element 7b′, e.g., in form of a lower housing component, with an inventive frame element 5′ and to arrange said housing elements with a seal 6 that surrounds said frame element respectively at a face 2a′ or 2b′ of the printed circuit board 2′, in the above described fashion, for the purpose of capping the components 3 populating said faces.

The frame element 5′ of the further embodiment is also intended for heat dissipation, and therefore, e.g., manufactured from thermally well-conducting material. In particular in case of a printed circuit board 2′ that is populated on both sides, which does not allow a direct connection between the components 3 that are populated on a face 2b′ or 2a′ of the printed circuit board and an adjacent heat sink or cooling unit of the other face 2a′ or 2b′ of the printed circuit board, e.g., adjacent to the housing element 7b′ or 7a′, so that heat dissipation via the frame 5′ is advantageous. For the purpose of heat dissipation, e.g., thermal vias, which are formed in the printed circuit board 2′, are connected to the frame 5′ supported on the printed circuit board 2′ in a thermally conductive manner, and said frame element 5′, in turn, is connected in a thermally conductive manner to the housing element 7b′ or 7a′, which is adjacent to the heat sink.

According to the invention, the frame element 5′ can include additional features, e.g., one or several flat cooling elements or fins 14 formed in the interior of the frame element, to which said cooling elements or fins respectively associate with relatively high heat generating components 3 for heat dissipation, e.g., with thermal vias, over the frame element 5′ and the respectively assigned housing element 7a′ or 7b′, which interacts with said frame element for sealing purposes. The cooling fins, together with the frame element 5′, e.g., can be manufactured in a single process step through punching. The cooling fins 14 extend, e.g., into the interior of the frame 5′ and overlap the printed circuit board 2′ in those areas, in which thermal vias are provided to components 3 for heat dissipation.

The invention intends to form a housing element 7a′ or 7b′ without transformation process in planar fashion, in particular a lower housing component 7b′, e.g., as punched sheet metal. Such a plate-shaped housing element 7a′ or 7b′ can abut advantageously against a heat sink, e.g., in form of a cooling element, with its entire surface laying flat on said heat sink. In addition, such a housing element 7 can abut against an IC incorporated in the printed circuit board 2′, e.g., a micro controller 4, if necessary with interposition of a heat conducting layer, for the purpose of heating said housing element.

In order to create space for high-built components 3, in a plate-shaped or flat housing element 7a′ or 7b′, material on the inner surface facing the component 3 can be removed to form a recess, into which the component 3 extends.

To form an inventive control device assembly 1′ in accordance with the above described further embodiment, as a first step, the separately manufactured frame element 5′ is provided and, in a further step, inserted into the provided housing element 7a′ or 7b′. In an optional further step the frame element 5′ is permanently fixed to the housing element 7a′ or 7b′. In a final step the seal 6 is arranged around the frame element 5′ and abuts against its outer circumferential surface 5a′. In a further step, the housing element 7a′ or 7b′, together with the frame element 5′ and the seal 6 abuts against the printed circuit board 2′ and permanently fixed to it, wherein said seal 6 is pressed against the printed circuit board 2′ on the one side and the housing element 7a′ or 7b′ on the other side. As a result of this, the electronic chamber 8 between printed circuit board 2′ and housing element 7a′ or 7b′ is sealed.

According to the invention it is generally envisaged to connect housing element 7a or 7a′ and housing element 7b or 7b′ with one or several straps 15, in a cost-effective manner through beading. The straps 15 are, e.g., formed integrally with one or both housing elements 7a, 7a′, 7b, 7b′ and can be welded together if a robust and mechanically strong housing is needed.

The inventive idea also includes the arrangement of a frame element 5 of the first embodiment at the first populated face 2a or 2b of the printed circuit board 2 and of a frame element 5′ of the second embodiment at a second populated face 2a or 2b of the printed circuit board 2. According to the invention, several frame elements 5 or 5′ per populated face 2a, 2a′ or 2b, 2b′ of the printed circuit board are conceivable, which respectively interact with a seal 6 and a respectively associated housing element 7a, 7a′ or 7b, 7b′ to form a media-tight electronic chamber 8, as described above.

The invention allows for advantageous use of thicker sheet metal for manufacturing housing elements 7a, 7a′, 7b, 7b′, insofar as no complex transformation is required. Thus a better heat dissipation is achievable.

### REFERENCE NUMBERS

1, 1′ control device assembly

2, 2′ printed circuit board

2a, 2a′ bottom face of printed circuit board

2b, 2b′ top face of printed circuit board

3 electronic component

4 micro controller

5, 5′ frame element

5a, 5a′ outer circumferential surface of frame element

5b, 5b′ contact surface

5c, 5c′ frame stay

6 seal

7a, 7a′ housing element (upper housing component)

7b, 7b′ housing element (lower housing component)

8 electronic chamber

9 edge

10 recess

11, 11′ contact area

12 capping area

13 offset area

14 cooling fin

15 strap

1. A control device assembly for a motor vehicle, comprising:
a printed circuit board, comprising a populated face for mounting an electronic component;
at least one frame element, for enclosing the electronic component, being supported on the populated face;
at least one seal, surrounding and abutting against an outer circumferential surface of the at least one frame element; and
at least one housing element, pressing the at least one seal against the printed circuit board to form at least one sealed electronic chamber.

2. The control device assembly according to claim 1, wherein the at least one frame element is formed separately from the at least one housing element and the printed circuit board.

3. The control device assembly according to claim 1, wherein the at least one frame element is plugged into the printed circuit board.

4. The control device assembly according to claim 1, wherein the at least one frame element is manufactured from one of plastic and sheet metal.

5. The control device assembly according to claim 1, wherein the at least one frame element is inserted into to the housing element.

6. The control device assembly according to claim 1, wherein the at least one housing element is plate-shaped.

7. The control device assembly according to claim 1, wherein the printed circuit board is connected to the at least one frame element in thermally conductive fashion and the at least one frame element is connected to the at least one housing element in thermally conductive fashion.

8. The control device assembly according to claim 1, wherein a profile of the at least one frame element is rectangular between the printed circuit board and the at least one housing element.

9. The control device assembly according to claim 1, the printed circuit board further comprising:
a first face; and
a second face opposing the first face;
wherein a first frame element of the at least one frame element is arranged on the first face and a second frame element of the at least one frame element is arranged on the second face.
a first seal of the at least one seal is pressed against the first face by a first housing element of the at least one housing element, forming a first sealed electronic chamber, and
a second seal of the at least one seal is pressed against the second face, thereby forming a second sealed electronic chamber.

10. The control device assembly according to claim 10, wherein at least one strap is arranged at the first housing element for connecting with the second housing element.
